(19) United States
(12) Patent Application Publication
(10) Pub. No.: US 2025/0016992 A1
(43) Pub. Date: Jan. 9, 2025

(54) SEMICONDUCTOR MEMORY DEVICE

(71) Applicant: SAMSUNG ELECTRONICS CO., LTD., Suwon-si (KR)

(72) Inventors: Juho Lee, Suwon-si (KR); Mintae Ryu, Suwon-si (KR); Youngseok Park, Suwon-si (KR); Seongjae Byeon, Suwon-si (KR); Younggeun Song, Suwon-si (KR)

(73) Assignee: SAMSUNG ELECTRONICS CO., LTD., Suwon-si (KR)

(21) Appl. No.: 18/763,801

(22) Filed: Jul. 3, 2024

(30) Foreign Application Priority Data
Jul. 5, 2023 (KR) 10-2023-0087397

(51) Int. Cl. H10B 12/00

(52) U.S. Cl. CPC H10B 12/482; H10B 12/315; H10B 12/488

(57) ABSTRACT

A semiconductor memory device includes a substrate, a conductive line disposed on the substrate, a horizontal channel portion extending in a first direction on the conductive line and partially covering the conductive line, a separation insulating layer disposed on the horizontal channel portion, a gate insulating layer including a first portion on the conductive line and a second portion that extends in a second direction that is perpendicular to the substrate, a vertical channel portion between the gate insulating layer and the separation insulating layer, the vertical channel portion extending in the second direction, and a spacer on the first portion of the gate insulating layer. A first material included in the horizontal channel portion is different from a second material included in the vertical channel portion.

### CROSS-REFERENCE TO RELATED APPLICATION

This application is based on and claims priority under 35 U.S.C. § 119 to Korean Patent Application No. 10-2023-0087397, filed on Jul. 5, 2023, in the Korean Intellectual Property Office, the disclosure of which being incorporated by reference herein in its entirety.

### BACKGROUND

Apparatuses and devices consistent with the present disclosure relate to a semiconductor memory device and, in particular, to a semiconductor memory device including a vertical channel transistor.

Owing to the development in electronics technology, down-scaling of semiconductor devices is being rapidly performed, and accordingly, a transistor having a channel layer adopting an oxide semiconductor material has been suggested in order to reduce leakage current via a channel region.

### SUMMARY

It is an aspect to provide a semiconductor memory device having improved device characteristics and improved reliability by performing channel forming processes in two stages.

It is another aspect to provide a semiconductor memory device.

According to an aspect of one or more embodiments, there is provided a semiconductor memory device comprising a substrate; a lower conductive line disposed on the substrate; a horizontal channel portion that contacts an upper surface of the lower conductive line and extends in a first direction that is parallel to the substrate; a separation insulating layer disposed on the horizontal channel portion and including a channel trench; a vertical channel portion in the channel trench on the lower conductive line, the vertical channel portion extending in a second direction that is perpendicular to the substrate along a sidewall of the separation insulating layer and contacting the horizontal channel portion and the lower conductive line; a first gate insulating layer formed on the upper surface of the lower conductive line and including a first material; a second gate insulating layer in the channel trench and covering the vertical channel portion in the second direction, the second gate insulating layer including a second material that is the same as the first material; an upper conductive line disposed on the second gate insulating layer in the channel trench; a conductive contact pattern on the vertical channel portion; and a capacitor structure including a lower electrode connected to the conductive contact pattern. A material in the horizontal channel portion has a different composition from a material in the vertical channel portion.

According to another aspect of one or more embodiments, there is provided a semiconductor memory device comprising a substrate; a conductive line disposed on the substrate; a horizontal channel portion extending in a first direction on the conductive line and partially covering the conductive line; a separation insulating layer disposed on the horizontal channel portion; a gate insulating layer comprising a first portion on the conductive line and a second portion that extends in a second direction that is perpendicular to the substrate; a vertical channel portion between the gate insulating layer and the separation insulating layer, the vertical channel portion extending in the second direction; and a spacer on the first portion of the gate insulating layer. A first material included in the horizontal channel portion is different from a second material included in the vertical channel portion.

According to yet another aspect of one or more embodiments, there is provided a semiconductor memory device comprising a substrate; a bit line extending in a first direction on the substrate; a channel structure provided on the bit line; a gate insulating layer surrounding a sidewall of the channel structure and an upper surface of the bit line; a spacer disposed on a horizontal portion of the gate insulating layer; and a word line that contacts an upper surface of the spacer and extends along a sidewall of the gate insulating layer in a second direction that is perpendicular to the substrate; a landing pad disposed on the channel structure; a capacitor structure including a lower electrode connected to the landing pad. The channel structure includes a horizontal channel portion that is parallel to the bit line and a vertical channel portion that protrudes perpendicularly from the upper surface of the bit line, and a composition of the vertical channel portion is different from a composition of the horizontal channel portion.

### BRIEF DESCRIPTION OF THE DRAWINGS

Various embodiments will be more clearly understood from the following detailed description taken in conjunction with the accompanying drawings, in which:

FIG. 1 is a planar layout showing some components of a semiconductor memory device according to an embodiment;

FIG. 2A is a cross-sectional view of the semiconductor memory device taken along line A-A′ of FIG. 1;

FIG. 2B is a cross-sectional view of the semiconductor memory device taken along line B-B′ of FIG. 1;

FIGS. 3A to 18 are cross-sectional views for describing a method of manufacturing a semiconductor memory device, according to an embodiment, wherein FIGS. 3A, 4A, 5A, 6, . . . , 18 are cross-sectional views taken along line A-A′ of FIG. 1, and FIGS. 3B, 4B, and 5B are cross-sectional views taken alone line B-B′ of FIG. 1.

### DETAILED DESCRIPTION

Hereinafter, one or more embodiments will be described in detail with reference to accompanying drawings. Like reference numerals denote the same elements on the drawings, and detailed descriptions thereof are omitted.

As embodiments consistent with the present disclosure allow for various changes and numerous embodiments, some embodiments will be illustrated in the drawings and described in detail in the written description. However, this is not intended to limit the embodiments to particular modes of practice, and it is to be appreciated that all modifications, equivalents, and/or alternatives that do not depart from the spirit and technical scope of the present disclosure are encompassed in the appended claims. In the description, certain detailed explanations are omitted when it is deemed that such detailed explanations may unnecessarily obscure the essence of the present disclosure.

In the specification, a vertical direction may be defined as a Z-direction and a horizontal direction may be defined as a direction perpendicular to the Z-direction. A first horizontal direction and a second horizontal direction may be defined as directions crossing each other. The first horizontal direction may be referred to as an X-direction and the second horizontal direction may be referred to as a Y-direction. An X-Y plane is defined as a plane perpendicular to the Z-direction and a Y-Z plane may be defined as a plane perpendicular to the X-direction. A vertical level may denote a height level in a vertical direction. As used in this specification, the phrase “at least one of A, B, and C” includes within its scope “only A”, “only B”, “only C”, “A and B”, “A and C”, “B and C” and “A, B, and C”.

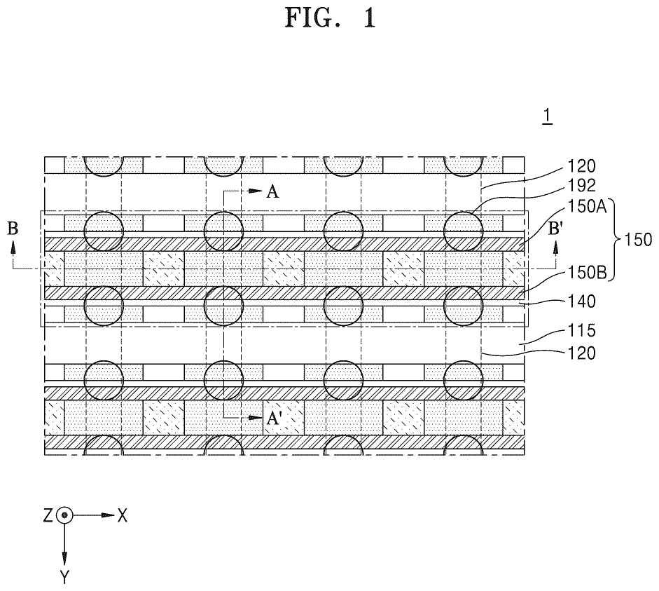

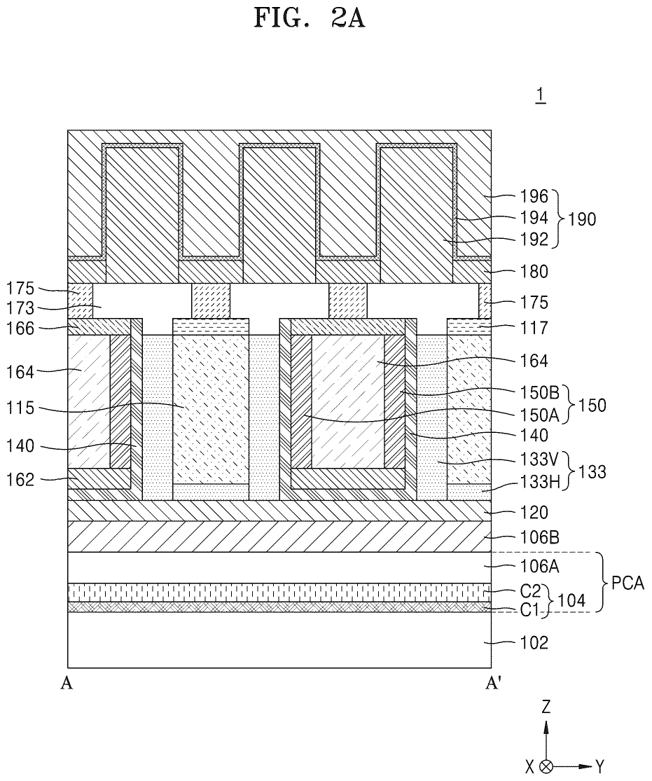

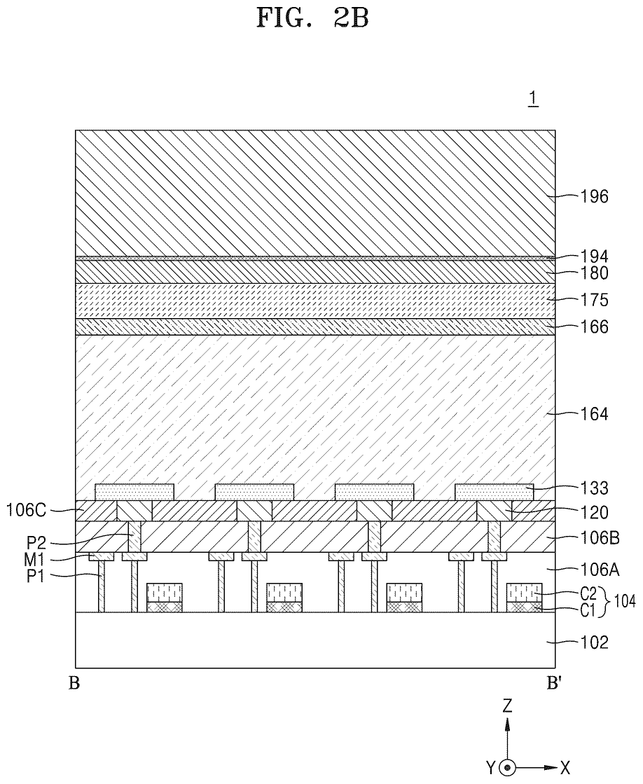

FIG. 1 is a planar layout showing some components of a semiconductor memory device 1 according to an embodiment. FIG. 2A is a cross-sectional view of the semiconductor memory device 1 taken along A-A′ of FIG. 1, and FIG. 2B is a cross-sectional view of the semiconductor memory device 1 taken along line B-B′ of FIG. 1.

Referring to FIGS. 1, 2A, and 2B, the semiconductor memory device 1 may include a substrate 102, a peripheral circuit structure PCA disposed on the substrate 102 and including a plurality of peripheral circuits, and a plurality of conductive lines 120 disposed on the peripheral circuit structure PCA. Each conductive line 120 may correspond to a bit line of the semiconductor memory device 1. In the specification, the conductive line 120 may be referred to as a lower conductive line.

In some embodiments, the substrate 102 may include silicon, e.g., single-crystalline silicon, polycrystalline silicon, or amorphous silicon. In some embodiments, the substrate 102 may include at least one selected from Ge, SiGe, SiC, GaAs, InAs, and InP. In some embodiments, the substrate 102 may include a conductive region, for example, a well doped with impurities or a structure doped with impurities.

The plurality of conductive lines 120 may be connected to at least one peripheral circuit from among the plurality of peripheral circuits included in the peripheral circuit structure PCA. The plurality of conductive lines 120 may be insulated from one another by an interlayer insulating layer 106C (see FIG. 2B). The plurality of conductive lines 120 may pass through the interlayer insulating layer 106C in a vertical direction (Z-direction). The plurality of conductive lines 120 may be connected to the peripheral circuits included in the peripheral circuit structure PCA via a plurality of conductive plugs P1 and P2 and a wiring layer M1 included in the peripheral circuit structure PCA.

The peripheral circuit structure PCA may include a plurality of core circuits 104. The plurality of core circuits 104 may include a first conductive pattern C1 and a second conductive pattern C2 sequentially disposed on the substrate 102. The first conductive pattern C1 and the second conductive pattern C2 may form various circuit elements for controlling functions of a semiconductor element disposed on the peripheral circuit structure PCA. In some embodiments, the peripheral circuit structure PCA may further include various active elements such as a transistor, and various passive elements such as a capacitor, a resistor, an inductor, etc.

In some embodiments, the plurality of peripheral circuits included in the peripheral circuit structure PCA may include a sub-word line driver, a sense amplifier block, and/or a control logic but embodiments are not limited thereto. The plurality of peripheral circuits included in the peripheral circuit structure PCA may include an NMOS transistor and a PMOS transistor. The plurality of peripheral circuits may be electrically connected to the conductive lines (e.g., bit lines) disposed on the peripheral circuit structure PCA via the plurality of conductive plugs P1 and P2 and the wiring layer M1.

In the peripheral circuit structure PCA, from among the plurality of core circuits 104, the plurality of conductive plugs P1 and P2, and the wiring layer M1, parts that are to be insulated from each other may maintain an insulating distance due to a plurality of interlayer insulating layers 106A, 106B, and 106C. The plurality of interlayer insulating layers 106A, 106B, and 106C may each include an oxide layer or a nitride layer, or a combination thereof but embodiments are not limited thereto.

In some embodiments, the peripheral circuit structure PCA may be omitted. In this case, the peripheral circuit structure PCA may be disposed in another region on the substrate 102, which is spaced apart from the example regions shown in FIGS. 2A and 2B. In some embodiments, the peripheral circuit structure PCA may be arranged in another region that is spaced apart from a cell array area in an axial direction.

The plurality of conductive lines 120 may be spaced apart from each other in a first horizontal direction (X-direction) on the substrate 102 and may extend long in a second horizontal direction (Y-direction). The plurality of conductive lines 120 may extend in parallel to each other in the second horizontal direction (Y-direction). In some embodiments, each of the conductive lines 120 may include Ti, TiN, Ta, TaN, Mo, Ru, W, WN, Co, La, Pd, Ni, TiSi, TiSiN, WSi, WSIN, TaSi, TaSiN, RuTiN, CoSi, NiSi ITO (InSnO), or polysilicon, or a combination thereof. However, embodiments are not limited thereto.

A separation insulating layer 115 may be disposed on the plurality of conductive lines 120. For example, the separation insulating layer 115 may be disposed on each channel structure 133 provided on the plurality of conductive lines 120. In some embodiments, a lower surface of the separation insulating layer 115 may come into contact with an upper surface of a horizontal channel portion 133H in each channel structure 133.

The separation insulating layer 115 may have a plurality of channel trenches 115t (see FIG. 6) extending in the first horizontal direction (X-direction). The plurality of channel trenches 115t may each define a transistor region in which the channel structure 133 is accommodated. In some embodiments, a horizontal width of the channel trench 115t may be a few nm to tens of nm. For example, in some embodiments, the horizontal width of the channel trench 115t may be about 3 nm to about 10 nm. The channel trench 115t may extend from the upper surface to the lower surface of the separation insulating layer 115.

The separation insulating layer 115 may include, for example, at least one of silicon oxide, silicon oxynitride, silicon nitride, and a low-k material having a dielectric constant less than a dielectric constant of the silicon oxide, but embodiments are not limited thereto. In some embodiments, a stack structure in which an etch stop layer 117 is thinly formed on the separation insulating layer 115 may be provided. In some embodiments, the etch stop layer 117 may include SiN.

The plurality of channel structures 133 may be provided in the plurality of channel trenches 115t of the separation insulating layer 115. The plurality of channel structures 133 may be respectively disposed on corresponding conductive lines 120. For example, in some embodiments, each of the plurality of conductive lines 120 may have a plurality of channel structures 133. The plurality of channel structures 133 may be spaced apart from each other in the first horizontal direction (X-direction) and may be spaced apart from each other in the second horizontal direction (Y-direction) and may be arranged in a matrix form. A lower surface of each channel structure 133 may face the upper surface of the conductive line 120. In some embodiments, an uppermost surface of each channel structure 133 may be at a lower vertical level than a vertical level of the upper surface of the stack structure formed by stacking the separation insulating layer 115 and the etch stop layer 117. In other words, the uppermost surface of each channel structure 133 maybe at a lower vertical level in the Z-direction than an uppermost surface of the etch stop layer 117.

Each channel structure 133 may include a vertical channel portion 133V facing a sidewall of the separation insulating layer 115 (that is, a sidewall of the separation insulating layer 115 defining the channel trench 115t), and a horizontal channel portion 133H facing the upper surface of the conductive line 120. In each of the channel structures 133, the horizontal channel portion 133H may come into direct contact with the conductive line 120 and may continuously extend in the first horizontal direction (X-direction) along the surface of the conductive line 120. In each of the channel structures 133, the vertical channel portion 133V may come into contact with the sidewall of the separation insulating layer 115 and may extend in the vertical direction (Z-direction) along the sidewall of the separation insulating layer 115 from the horizontal channel portion 133H. In other words, the vertical channel portion 133V may contact the sidewall of each of the separation insulating layer 115 and a sidewall of the horizontal channel portion 133H. In some embodiments, in each of the channel structures 133, a lower surface of the vertical channel portion 133V may be disposed on the conductive line 120. In some embodiments, the upper surface of the vertical channel portion 133V may be at a lower vertical level than a vertical level of the upper surface of the separation insulating layer 115. Each channel structure 133 may include one horizontal channel portion 133H, the vertical channel portion 133V connected to one side of the horizontal channel portion 133H, and the vertical channel portion 133V connected to the other side of the horizontal channel portion 133H. As shown in FIG. 2A, when it seen from the cross-section, each channel structure 133 may have a U-shaped vertical section. That is, each channel structure 133 may have a U-shape on the Y-Z plane.

In some embodiments, the horizontal channel portion 133H may include IGZO (InGaZnO), ITO (InSnO), IWO (InWO), or polysilicon, or a combination thereof. In some embodiments, the vertical channel portion 133V may include IGZO (InGaZnO), ITO (InSnO), IWO (InWO), IGO (InGaO), or n-type polysilicon, or a combination thereof. In some embodiments, the horizontal channel portion 133H and the vertical channel portion 133V may include different materials from each other. That is, in some embodiments, materials included in the horizontal channel portion 133H may be different than materials included in the vertical channel portion 133V. In some embodiments, the materials included in the horizontal channel portion 133H and the vertical channel portion 133V may exhibit different characteristics. For example, the horizontal channel portion 133H and the vertical channel portion 133V may both include IGZO, but the IGZO included in the horizontal channel portion 133H may have high-mobility IGZO composition as compared with the IGZO included in the vertical channel portion 133V. In some embodiments, the horizontal channel portion 133H may include a material having higher electron mobility than an electron mobility of a material of the vertical channel portion 133V. In some embodiments, the material included in the horizontal channel portion 133H may have a lower contact resistivity than a contact resistivity of the material included in the vertical channel portion 133V.

The plurality of channel structures 133 arranged in the second horizontal direction (Y-direction) may be disposed on each conductive line 120. A lower surface of each horizontal channel portion 133H may come into direct contact with the upper surface of the corresponding conductive line 120.

As shown in FIG. 2A, when seen from the cross-section, each horizontal channel portion 133H may have a rectangular shape of which the length in the second horizontal direction (Y-direction) is greater than a length in the vertical direction (Z-direction). A thickness of each horizontal channel portion 133H in the vertical direction (Z-direction) may range from about a few nm to tens of nm. For example, in some embodiments, the thickness of each horizontal channel portion 133H in the vertical direction (Z-direction) may range from 3 nm to 10 nm.

As shown in FIG. 2A, when seen from the cross-section, each vertical channel portion 133V may have a rectangular shape of which the length in the vertical direction (Z-direction) is greater than a length in the second horizontal direction (Y-direction). A thickness of each vertical channel portion 133V in the second horizontal direction (Y-direction) may range from about a few nm to tens of nm. For example, in some embodiments, the thickness of each vertical channel portion 133V in the second horizontal direction (Y-direction) may range from 3 nm to 10 nm. In some embodiments, a thickness of each horizontal channel portion 133H in the vertical direction (Z-direction) is different from a thickness of each vertical channel portion 133V in the second horizontal direction (Y-direction).

The semiconductor memory device 1 may include a vertical channel transistor (VCT). The VCT may denote a structure in which a channel length of a channel layer, e.g., the channel structure 133, extends in the vertical direction (Z-direction) that is perpendicular to the upper surface of the substrate 102. For example, the channel structure 133 may include a first source/drain region and a second source/drain region arranged in the vertical direction (Z-direction). For example, a lower portion of the channel structure 133 may include the first source/drain region, the upper portion of the channel structure 133 may include the second source/drain region, and the channel structure 133 may include a channel region between the first source/drain region and the second source/drain region.

A gate insulating layer 140 may extend along the surface of the channel structure 133 provided in the channel trench 115t. The gate insulating layer 140 may be disposed between the channel structure 133 and a word line 150. In some embodiments, the uppermost end of the gate insulating layer 140 may be at a higher vertical level than a vertical level of the uppermost end of the word line 150. In some embodiments, the gate insulating layer 140 may extend along the upper surface of the conductive line 120 and the side surface of the vertical channel portion 133V facing a gap-fill insulating layer 164. In this specification, the portion of the gate insulating layer 140 that extends along the upper surface of the conductive line 120 may be referred to as a first gate insulating layer and the portion of the gate insulating layer 140 have extends along the side surface of the vertical channel portion 133V facing the gap-fill insulating layer 164 may be referred to as a second gate insulating layer. In some embodiments, a thickness of the first gate insulating layer in the vertical direction (Z-direction) may be equal to a thickness of the second gate insulating layer in the horizontal direction (Y-direction), and the first gate insulating layer and the second gate insulating layer may be integrally formed with each other. For example, the gate insulating layer 140 formed in a U-shape on the Y-Z plane may be arranged along an outer surface of one channel structure forming a U-shaped vertical section, an outer surface of another channel structure adjacent to the above channel structure, and a separation space between the adjacent channel structures. The gate insulating layer 140 may extend in the vertical direction (Z-direction) from a lower portion thereof that contacts the conductive line 120, and the uppermost end of the gate insulating layer 140 may be at a vertical level that is higher than a vertical level of the upper surface of the vertical channel portion 133V. The gate insulating layer 140 may include, but is not limited to, for example, at least one of silicon oxide, silicon oxynitride, silicon nitride, and a high-k material having a dielectric constant greater than a dielectric constant of the silicon oxide.

In some embodiments, a spacer 162 may be provided on a region formed in parallel to the XY plane, in the gate insulating layer 140 formed in a U-shape. Because the spacer 162 is formed on the gate insulating layer 140, a distance between the conductive line 120 and the word line 150 may be secured, and accordingly, the reliability of the semiconductor memory device 1 may be improved.

The word line 150 may be provided on the gate insulating layer 140 and the spacer 162 provided in the channel trench 115t. The word line 150 may extend in the vertical direction (Z-direction) along the gate insulating layer 140 provided in the channel trench 115t. The word line 150 may extend in the first horizontal direction (X-direction). The word line 150 may include doped polysilicon, metal, conductive metal nitride, conductive metal silicide, or conductive metal oxide, or a combination thereof. For example, the word line 150 may include, but is not limited to, doped polysilicon, Al, Cu, Ti, Ta, Ru, W, Mo, Pt, Ni, Co, TiN, TaN, WN, NbN, TiAl, TiAIN, TiSi, TiSiN, TaSi, TaSiN, RuTiN, NiSi, CoSi, IrOx, or RuOx, or a combination thereof.

In some embodiments, the word line 150 may include a first word line 150A and a second word line 150B facing each other in one channel trench 115t. The first word line 150A and the second word line 150B may be spaced apart from each other in the second horizontal direction (Y-direction) and may extend long in the first horizontal direction (X-direction), respectively. In one channel trench 115t, the channel structure 133 and the first word line 150A are spaced apart from each other by the gate insulating layer 140 formed in the U-shape, and the channel structure 133 and the second word line 150B may be spaced apart from each other by the same gate insulating layer 140. The gate insulating layer 140 arranged between the channel structure 133 and the first word line 150A and the gate insulating layer 140 arranged between the channel structure 133 and the second word line 150B may each have a U-shaped vertical section and may be integrally connected to each other. In the specification, the word line 150 may be referred to as an upper conductive line. Also, the first word line 150A may be referred to as a first upper conductive line and the second word line 150B may be referred to as a second upper conductive line.

In some embodiments, the gap-fill insulating layer 164 may be provided between the first word line 150A and the second word line 150B. The first word line 150A and the second word line 150B may be isolated from each other by the gap-fill insulating layer 164. The gap-fill insulating layer 164 may be provided to fill the inside of the U-shaped vertical section formed by the first word line 150A, the second word line 150B, and the spacer 162 and may fill the gap between the first word line 150A and the second word line 150B.

In one channel trench 115t, the first word line 150A and the second word line 150B may be isolated from each other by the gap-fill insulating layer 164.

The gap-fill insulating layer 164 may include, but is not limited to, at least one of silicon oxide, silicon oxynitride, silicon nitride, and a combination thereof. In some embodiments, the gap-fill insulating layer 164 may include a high-k material having a dielectric constant greater than a dielectric constant of silicon oxide.

An insulating capping pattern 166 may be disposed on the word line 150 and the gap-fill insulating layer 164. The insulating capping pattern 166 may be formed to, for example, cover the upper surface of the word line 150 and the upper surface of the gap-fill insulating layer 164 and to be co-planar with the upper surface of the gate insulating layer 140 while coming into contact with the gate insulating layer 140. The insulating capping pattern 166 may include, but is not limited to, silicon nitride. In some embodiments, the gate insulating layer 140 may extend along the side surface of the word line 150 and the side surface of the insulating capping pattern 166 and may cover the side surfaces of the word line 150 and the insulating capping pattern 166. In some embodiments, the upper surface of the gate insulating layer 140 and the upper surface of the insulating capping pattern 166 may be at the same vertical level and may be co-planar.

A plurality of conductive contact patterns 173 may be disposed on the plurality of channel structures 133. The plurality of conductive contact patterns 173 may be each connected to one channel structure 133 among the plurality of channel structures 133. For example, the plurality of conductive contact patterns 173 may be spaced apart from one another in the first horizontal direction (X-direction) and the second horizontal direction (Y-direction) and may be arranged in a matrix form on the XY plane. The plurality of conductive contact patterns 173 may electrically connect the channel structures 133 to corresponding capacitor structures 190. The conductive contact pattern 173 may include a conductive material, for example, at least one of metal, conductive metal nitride, conductive metal carbonitride, conductive metal carbide, metal silicide, doped semiconductor material, and conductive metal oxynitride. The conductive contact pattern 173 may come into contact with a lower electrode 192 of a capacitor structure 190 and may be referred to as a landing pad.

The plurality of conductive contact patterns 173 may be insulated from one another by insulating structures 175. The insulating structures 175 may be disposed on the etch stop layer 117 and the insulating capping pattern 166. In some embodiments, the insulating structure 175 may include a nitride material. In FIG. 2A, an upper surface of the insulating structure 175 and upper surfaces of the plurality of conductive contact patterns 173 are at the same vertical level, but embodiments are not limited thereto. For example, in some embodiments, the upper surface of the insulating structure 175 may be at a higher level than a level of the upper surfaces of the plurality of conductive contact patterns 173. In FIGS. 2A and 2B, a lower surface of the insulating structure 175 is shown to be at the same vertical level as the upper surface of the etch stop layer 117 and the upper surface of the insulating capping pattern 166, but embodiments are not limited thereto. For example, in some embodiments, the insulating structure 175 may extend into the etch stop layer 117 and/or into the insulating capping pattern 166 so that the lower surface of the insulating structure 175 may be at a lower vertical level than a vertical level of the upper surface of the etch stop layer 117 and/or a vertical level of the upper surface of the insulating capping pattern 166.

A support insulating layer 180 may be disposed on the plurality of conductive contact patterns 173 and the insulating structure 175. The support insulating layer 180 may cover the plurality of conductive contact patterns 173 and the insulating structures 175 and may have a plurality of holes overlapping the plurality of conductive contact patterns 173. The support insulating layer 180 may include, for example, silicon nitride layer or silicon boron nitride (SiBN).

A plurality of capacitor structures 190 may be disposed on the plurality of conductive contact patterns 173. The plurality of capacitor structures 190 may be respectively connected to corresponding conductive contact patterns 173, from among the plurality of conductive contact patterns 173. The capacitor structure 190 may be controlled by the conductive line 120 and the word line 150 to store the data.

The plurality of capacitor structures 190 may include a plurality of lower electrodes 192, a capacitor dielectric layer 194, and an upper electrode 196. The plurality of capacitor structures 190 may each store electric charges in the capacitor dielectric layer 194 by using the potential difference between the lower electrodes 192 and the upper electrode 196.

The plurality of lower electrodes 192 may be connected to the plurality of conductive contact patterns 173. For example, the plurality of lower electrodes 192 may be connected to the upper surfaces of the plurality of conductive contact patterns 173, which are exposed via the plurality of holes in the support insulating layer 180. In FIG. 2A, the lower electrode 192 is shown to have a pillar shape extending in the vertical direction (Z-direction) from the upper surface of the conductive contact pattern 173 but embodiments are not limited thereto. In some embodiments, the lower electrode 192 may have a cylinder shape extending in the vertical direction (Z-direction) from the upper surface of the conductive contact pattern 173. In some embodiments, the plurality of lower electrodes 192 may be arranged in a matrix formed on the XY plane. In some embodiments, the plurality of lower electrodes 192 may be arranged in a honeycomb shape on the XY plane. The lower electrode 192 may include silicon doped with impurities, a metal such as tungsten or copper, or a conductive metal compound such as titanium nitride.

The capacitor dielectric layer 194 may be formed on the plurality of lower electrodes 192. In some embodiments, the capacitor dielectric layer 194 may conformally extend along the side and upper surfaces of the plurality of lower electrodes 192 and the upper surface of the support insulating layer 180. The capacitor dielectric layer 194 may include, for example, TaO, TaAIO, TaON, AIO, AlSiO, HfO, HfSiO, ZrO, ZrSiO, TiO, TiAIO, BST((Ba,Sr)TiO), STO(SrTiO), BTO(BaTiO), PZT(Pb(Zr,Ti)O), (Pb,La) (Zr,Ti)O, Ba(Zr,Ti)O, or Sr(Zr,Ti)O, or a combination thereof.

The upper electrode 196 may be formed on the capacitor dielectric layer 194. The upper electrode 196 may include a metal material. For example, the upper electrode 196 may include W, Ru, RuO, Pt, PtO, Ir, IrO, SRO(SrRuO), BSRO((Ba,Sr)RuO), CRO(CaRuO), BaRuO, or La(Sr,Co)O, or a combination thereof. In some embodiments, the upper electrode 196 may further include at least one of a doped semiconductor material layer and an interfacial layer in addition to the metal material and may have a stack structure thereof. The doped semiconductor material may include, for example, at least one of the doped polysilicon and doped polycrystalline silicon germanium (SiGe). The interfacial layer may include, for example, at least one of metal oxide, metal nitride, metal carbide, and metal silicide.

According to the semiconductor memory device 1, because processes of forming the horizontal portion 133H and the vertical portion 133V of the channel structure 133 are separately performed when performing the process of forming the channel in the vertical channel transistor, the horizontal portion 133H and the vertical portion 133V may have different doping concentrations, may have different compositions, or may include different materials, and thus, the performance of the semiconductor memory device 1 may be improved. By adding the spacer 162 between the conductive line 120 and the word line 150, the distance between the conductive line 120 and the word line 150 may be secured, and thus, reliability of the semiconductor memory device 1 may be improved.

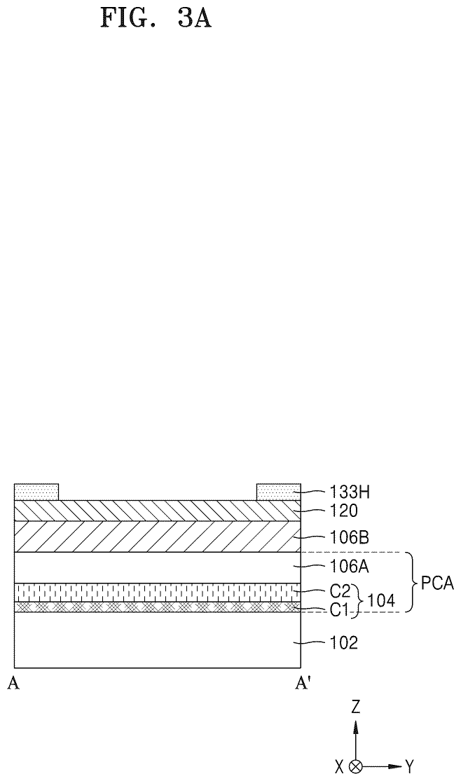

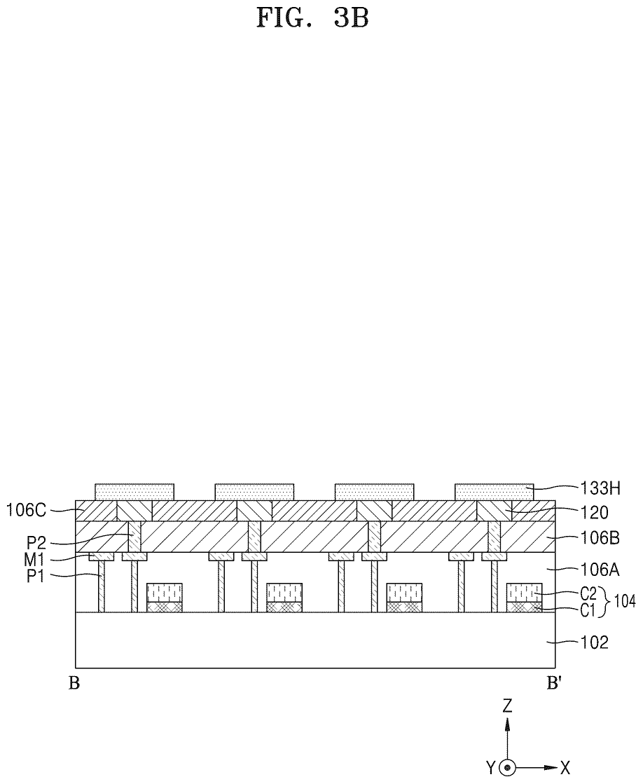

FIGS. 3A to 18 are cross-sectional views for describing a method of manufacturing the semiconductor memory device 1, according to some embodiments. In detail, FIGS. 3A to 18 are cross-sectional views for describing the method of manufacturing the semiconductor memory device 1 shown in FIGS. 1 to 2B, and FIGS. 3A, 4A, 5A, 6, . . . , 18 are cross-sectional views of the semiconductor memory device 1 taken along line A-A′ of FIG. 1, and FIGS. 3B, 4B, and 5B are cross-sectional views of the semiconductor memory device 1 taken alone line B-B′ of FIG. 1.

Referring to FIGS. 3A and 3B, a plurality of peripheral circuits including a plurality of core circuits 104, a plurality of conductive plugs P1 and P2, and a wiring layer M1 are formed on a substrate 102, and thus, a peripheral circuit structure PCA may be formed on the substrate 102. After that, an interlayer insulating layer 106C provided on the peripheral circuit structure PCA and a plurality of conductive lines 120 penetrating through the interlayer insulating layer 106C may be formed. Next, a horizontal channel layer covering the plurality of conductive lines 120 and the interlayer insulating layer 106C is formed, and the horizontal channel layer is patterned to form the plurality of horizontal channel portions 133H. The plurality of horizontal channel portions 133H may be formed of a material having a first composition as described above with reference to FIGS. 1-2B.

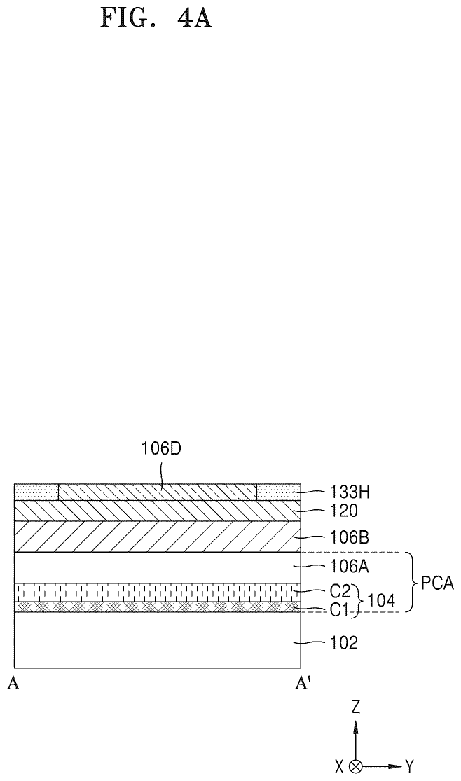

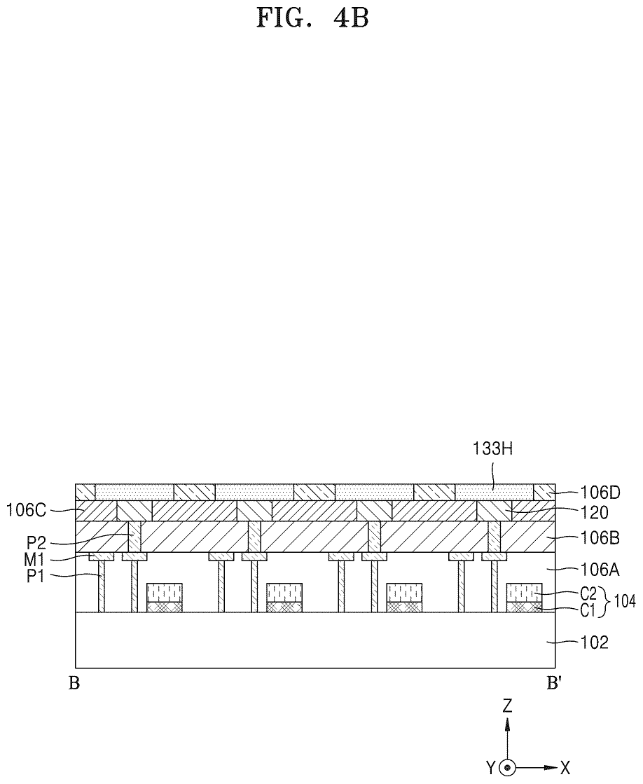

Referring to FIGS. 4A and 4B, after forming the plurality of horizontal channel portions 133H, a separation insulating film 106D covering the plurality of horizontal channel portions 133H and the interlayer insulating layer 106C is formed. In some embodiments, the separation insulating film 106D may include an oxide material.

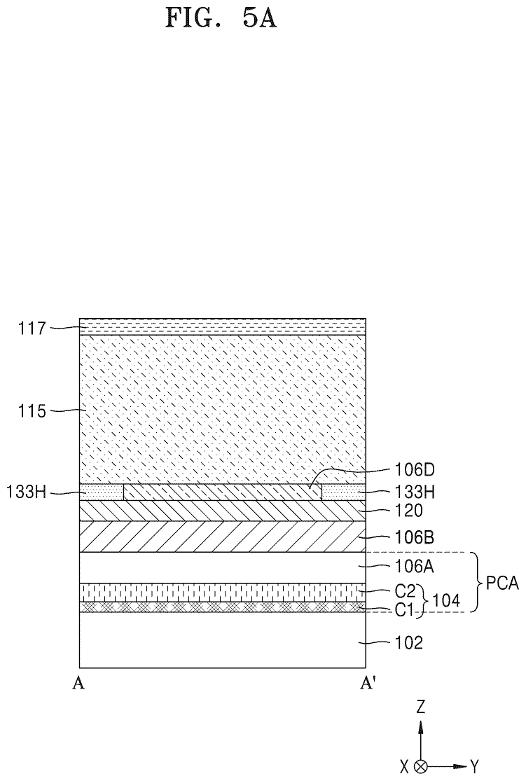

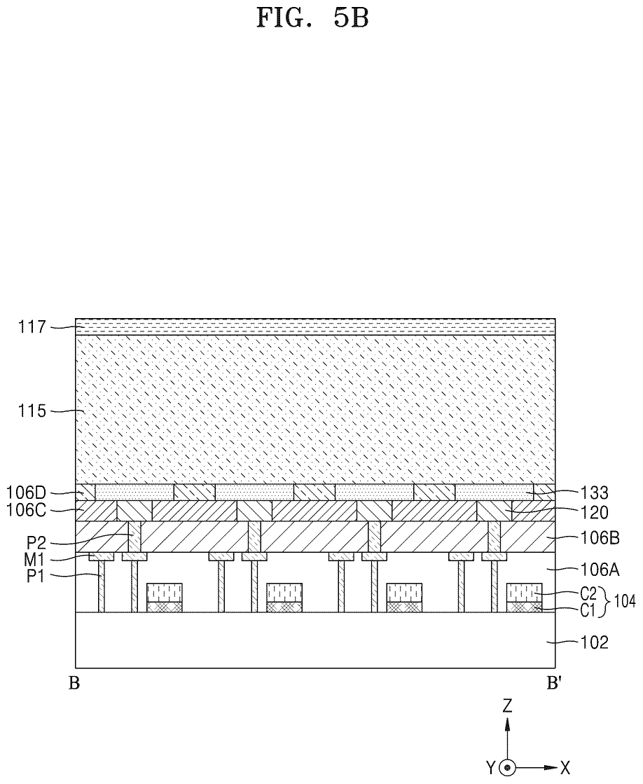

Referring to FIGS. 5A and 5B, the separation insulating layer 115 and the etch stop layer 117 may be sequentially formed to cover the surface of the resultant structure shown in FIGS. 4A and 4B. In some embodiments, the separation insulating layer 115 may be a first mold layer. In some embodiments, the etch stop layer 117 may include SiN.

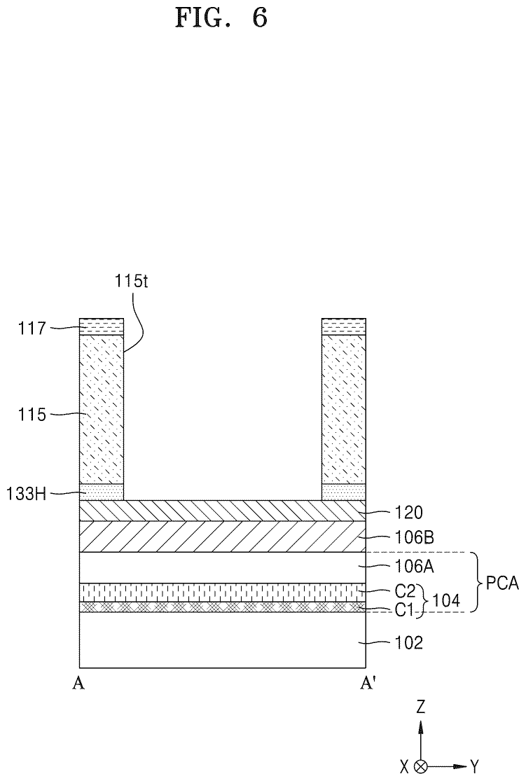

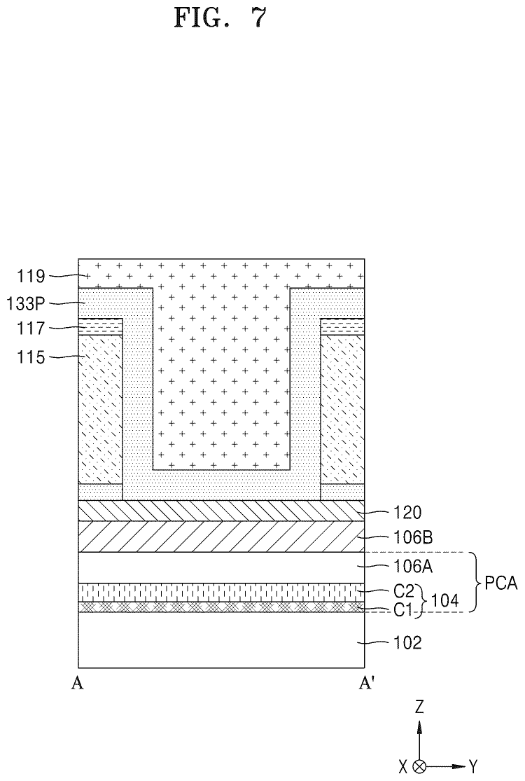

Referring to FIGS. 6 and 7, the etch stop layer 117, the separation insulating layer 115, and the separation insulating film 106D are sequentially etched, and then, a preliminary horizontal channel layer 133P covering the surface of the resultant of FIG. 6 may be formed. The preliminary horizontal channel layer 133P may be formed of a material having a second composition that is different from the first composition, as described above with reference to FIGS. 1-2B. The preliminary horizontal channel layer 133P may cover the upper surface of the conductive line 120, the side surface of the separation insulating layer 115, and the upper and side surfaces of the etch stop layer 117. After that, a second mold layer 119 filling a space in the preliminary horizontal channel layer 133P and covering the upper surface of the preliminary horizontal channel layer 133P may be formed.

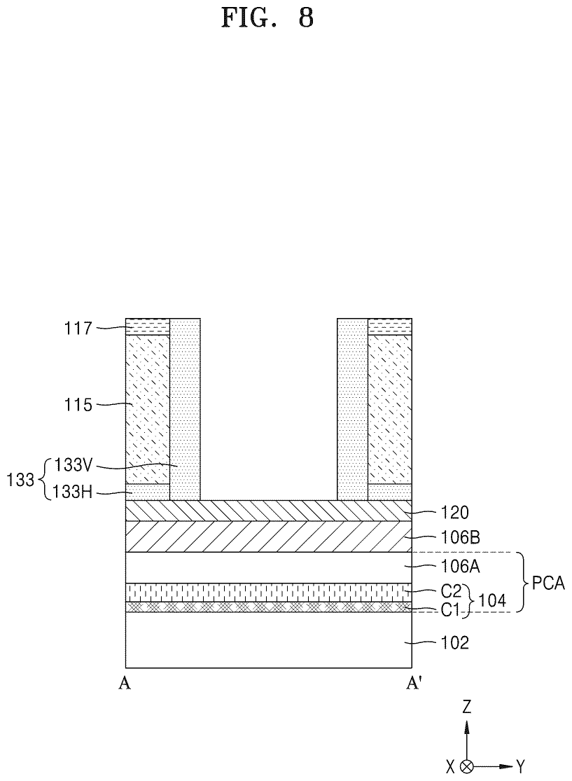

Referring to FIG. 8 along with FIG. 7, the second mold layer 119 (see FIG. 7) and some parts of the preliminary horizontal channel layer 133P covering the etch stop layer 117 and the conductive line 120 may be removed. The second mold layer 119 (see FIG. 7) and some parts of the preliminary horizontal channel layer 133P may be removed through an etch-back process. After the etch-back process on the preliminary horizontal channel layer 133P, remaining parts of the preliminary horizontal channel layer 133P may form the plurality of vertical channel portions 133V.

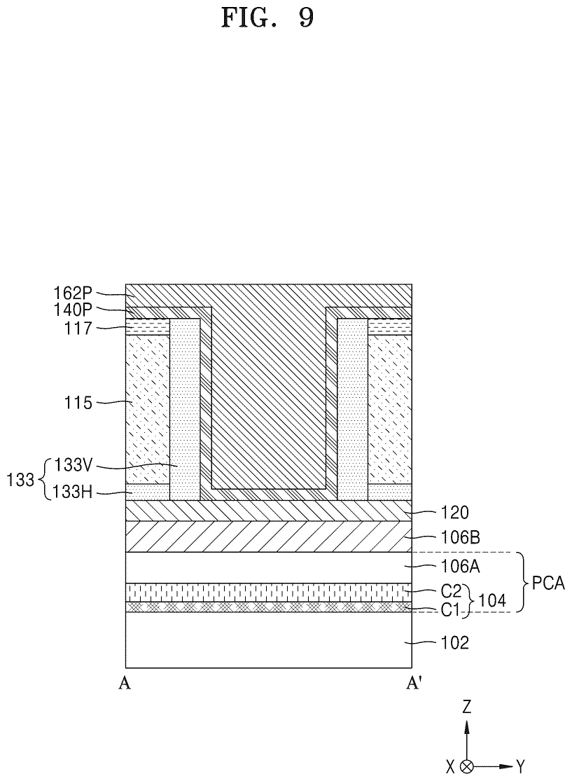

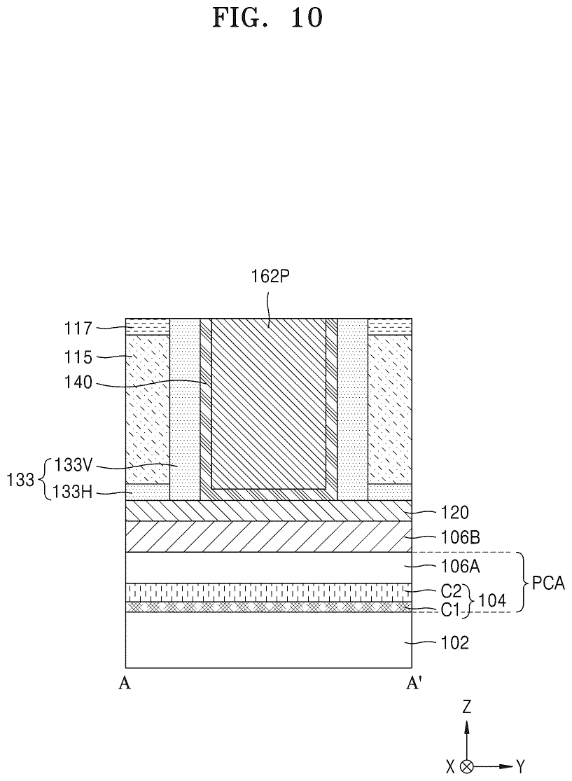

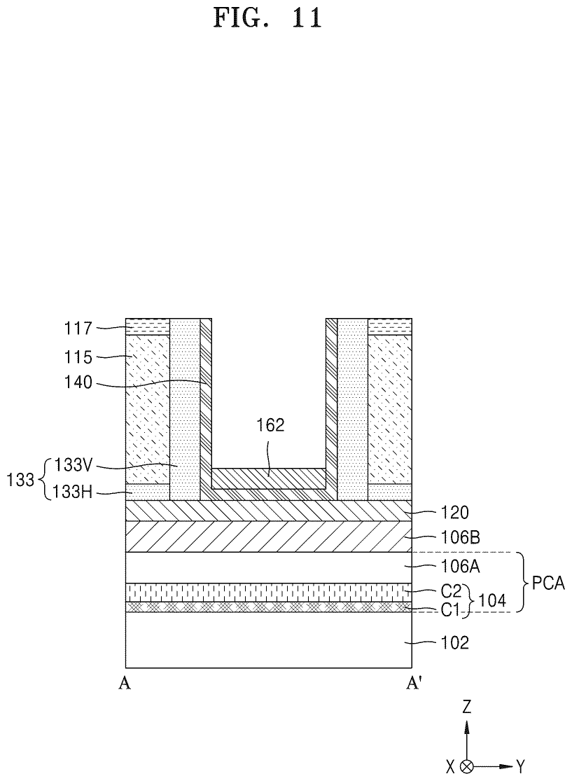

Referring to FIGS. 9, 10, and 11, a preliminary gate insulating layer 140P conformally covering the upper surface of the conductive line 120, the upper surface of the etch stop layer 117, and the upper and side surfaces of the plurality of vertical channel portions 133V is formed, and a preliminary spacer layer 162P covering the preliminary gate insulating layer 140P may be formed. In some embodiments, the preliminary spacer layer 162P may include SiN. When a chemical mechanical polishing (CMP) process is performed on the preliminary spacer layer 162P by using the etch stop layer 117 as an etch stop layer, as shown in FIG. 10, the gate insulating layer 140 and the preliminary spacer layer 162P that is co-planar with the upper surface of the gate insulating layer 140 may be obtained. After that, an etch-back process is performed on the preliminary spacer layer 162P to form the spacer 162 as shown in FIG. 11.

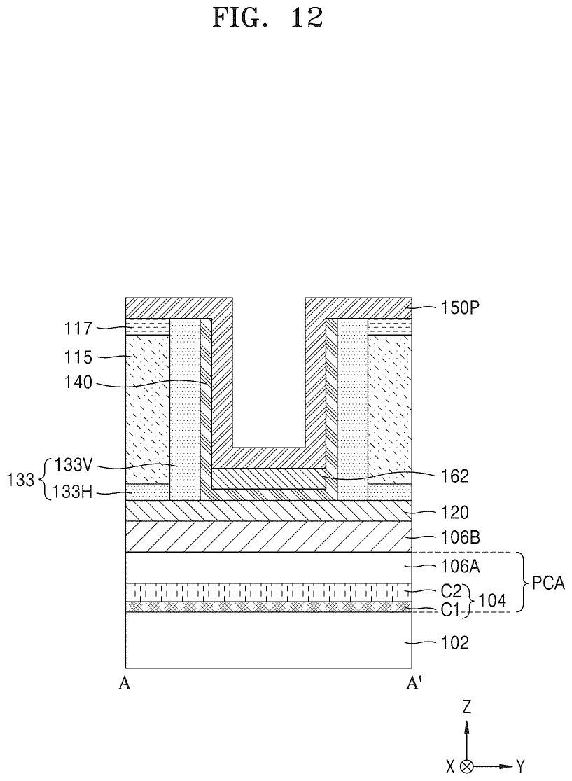

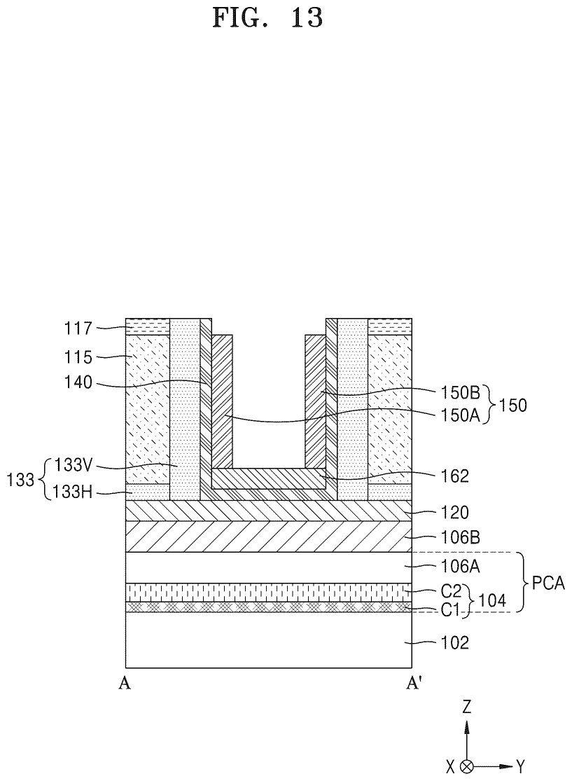

Referring to FIGS. 12 and 13, a preliminary word line material layer 150P conformally covering the upper surface of the etch stop layer 117, the upper surface of each channel structure 133, the side surface of the gate insulating layer 140, and the upper surface of the spacer 162 is formed on the resultant of FIG. 11. After that, a CMP process is performed on the preliminary word line material layer 150P by using the etch stop layer 117 as an etch stop layer, and a part of the preliminary word line material layer 150P covering the upper surface of the spacer 162 and a part of the preliminary word line material layer 150P covering the sidewall and part of the upper portion of the gate insulating layer 140 are removed to form the word lines 150. For example, in order to remove the part of the preliminary word line material layer 150P covering the upper surface of the spacer 162 and the part of the preliminary word line material layer 150P covering the sidewall and part of the upper portion of the gate insulating layer 140, an anisotropic etching may be performed on the preliminary word line material layer 150P. In some embodiments, the word line 150 may be formed to include a first word line 150A and a second word line 150B facing each other on one gate insulating layer 140.

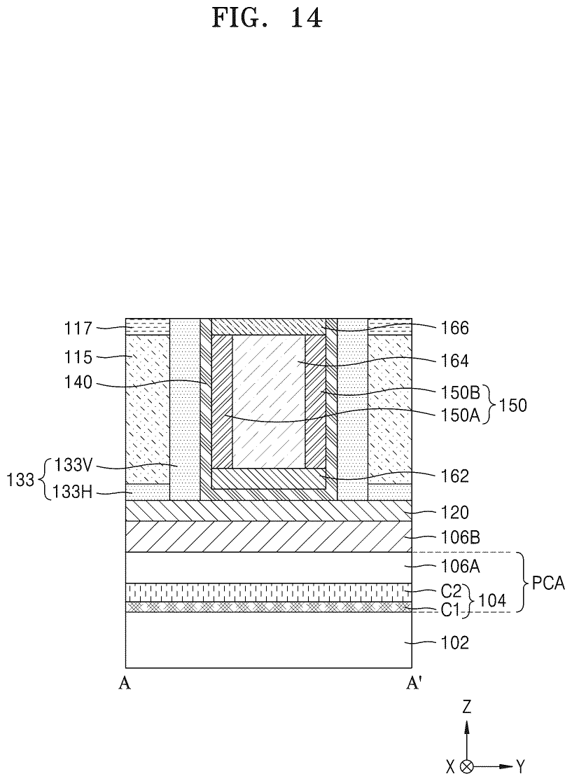

Referring to FIG. 14, the gap-fill insulating layer 164 covering the word line 150 and the spacer 162 is formed so as to fill the space defined by the word line 150 and the spacer 162 in the channel trench 115t. After that, on the gap-fill insulating layer 164, the insulating capping pattern 166 covering the upper side surface of the gate insulating layer 140, the upper surface of the gap-fill insulating layer 164, and the upper surface of the word line 150 may be formed.

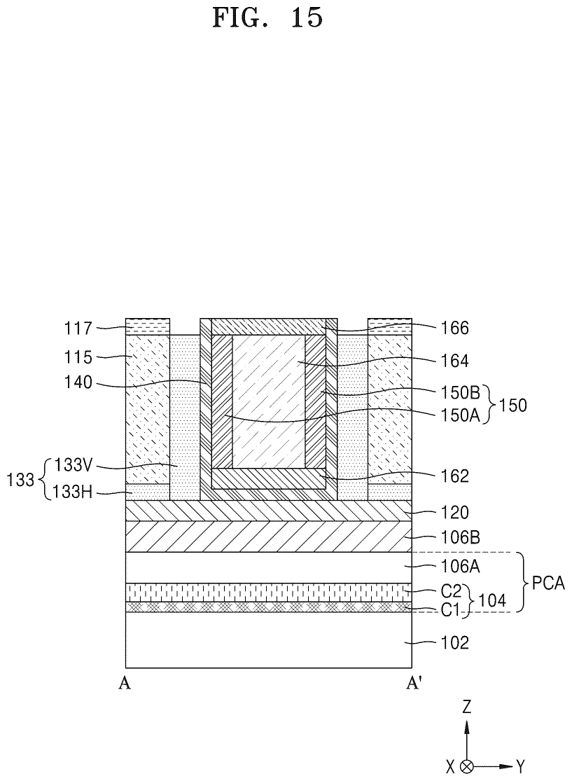

Referring to FIG. 15, the upper side of the vertical portion 133V in the channel structure 133 is partially removed from the resultant of FIG. 14. As the upper side of the vertical portion 133V is partially removed, the uppermost end of the channel structure 133 may be at a lower vertical level than a vertical level of the uppermost end of the word line 150.

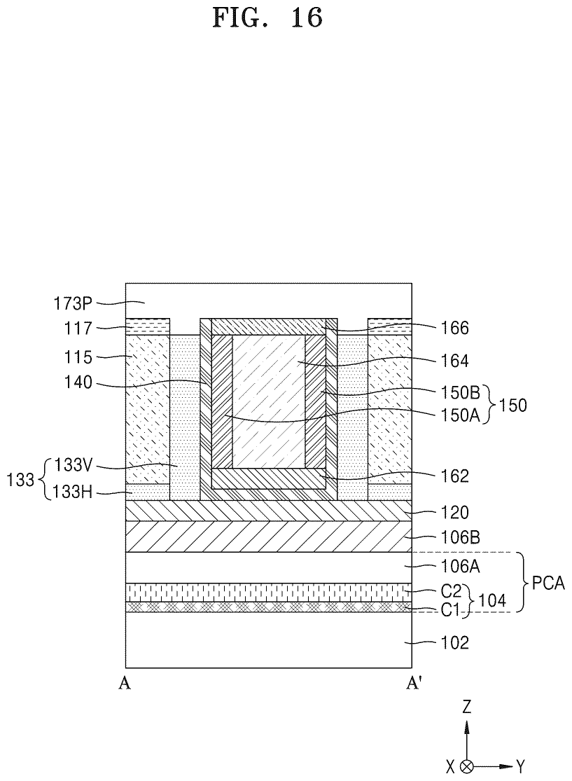

Referring to FIG. 16, a contact material layer 173P is formed on the resultant of FIG. 15. The contact material layer 173P may fill the space defined between the sidewall of the etch stop layer 117 and the gate insulating layer 140 and come into contact with the upper surface of the vertical portion 133V of the channel structure 133. The contact material 173P may cover the upper surface of the etch stop layer 117 and the upper surface of the insulating capping pattern 166.

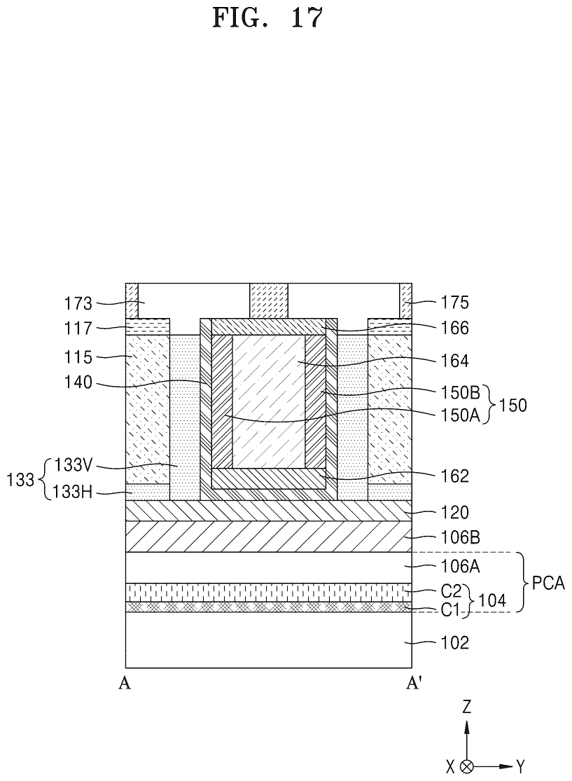

Referring to FIG. 17, the contact material layer 173P may be partially removed. For example, a mask pattern is formed on the contact material layer 173P, and the contact material layer 173P may be partially removed by using the mask pattern as an etching mask. The contact material layer 173P is partially removed to form a plurality of conductive contact patterns 173. The insulating structure 175 is formed in a space that is obtained by partially removing the contact material layer 173P.

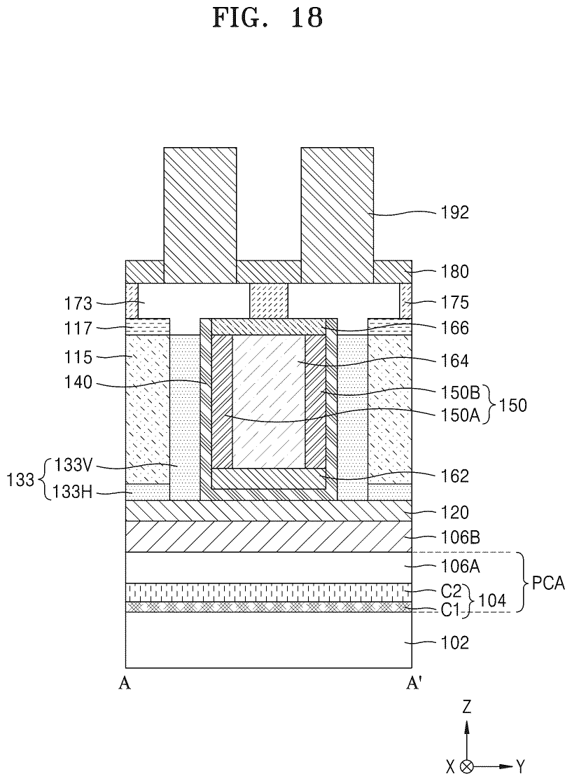

Referring to FIG. 18, the support insulating layer 180 is formed on the plurality of conductive contact patterns 173 and the insulating structure 175. The support insulating layer 180 may have a plurality of holes exposing the plurality of conductive contact patterns 173. After that, the plurality of lower electrodes 192 are formed on the plurality of conductive contact patterns 173. The plurality of lower electrodes 192 may be formed to extend in the vertical direction (Z-direction) from the upper surfaces of the conductive contact patterns 173, which are exposed by the plurality of holes of the support insulating layer 180.

Next, referring to FIGS. 2A and 2B, the capacitor dielectric layer 194 and the upper electrode 196 are sequentially formed on the plurality of lower electrodes 192, and the semiconductor memory device 1 including the plurality of capacitor structures 190 may be formed.

While various embodiments have been particularly shown and described with reference to the drawings, it will be understood that various changes in form and details may be made therein without departing from the spirit and scope of the following claims.

What is claimed is:

1. A semiconductor memory device comprising:
a substrate;
a lower conductive line disposed on the substrate;
a horizontal channel portion that contacts an upper surface of the lower conductive line and extends in a first direction that is parallel to the substrate;
a separation insulating layer disposed on the horizontal channel portion and including a channel trench;
a vertical channel portion in the channel trench on the lower conductive line, the vertical channel portion extending in a second direction that is perpendicular to the substrate along a sidewall of the separation insulating layer and contacting the horizontal channel portion and the lower conductive line;
a first gate insulating layer formed on the upper surface of the lower conductive line and including a first material;
a second gate insulating layer in the channel trench and covering the vertical channel portion in the second direction, the second gate insulating layer including a second material that is the same as the first material;
an upper conductive line disposed on the second gate insulating layer in the channel trench;
a conductive contact pattern on the vertical channel portion; and
a capacitor structure including a lower electrode connected to the conductive contact pattern,
wherein a material in the horizontal channel portion has a different composition from a material in the vertical channel portion.

2. The semiconductor memory device of claim 1, wherein a thickness of the horizontal channel portion in the second direction is different from a thickness of the vertical channel portion in the first direction.

3. The semiconductor memory device of claim 2, wherein:
the thickness of the horizontal channel portion in the second direction ranges from about 3 nm to about 10 nm, and
the thickness of the vertical channel portion in the first direction ranges from about 3 nm to about 10 nm.

4. The semiconductor memory device of claim 1, wherein the material in the horizontal channel portion includes high-mobility IGZO(InGaZnO), ITO(InSnO), IWO(InWO), or n-type polysilicon, or a combination thereof.

5. The semiconductor memory device of claim 1, wherein the material in the vertical channel portion includes low-mobility IGZO(InGaZnO), ITO(InSnO), IWO(InWO), or polysilicon, or a combination thereof.

6. The semiconductor memory device of claim 1, further comprising a spacer disposed on the first gate insulating layer.

7. The semiconductor memory device of claim 1, wherein a thickness of the first gate insulating layer in the second direction is equal to a thickness of the second gate insulating layer in the first direction, and the first gate insulating layer and the second gate insulating layer are integrally formed with each other.

8. The semiconductor memory device of claim 1, wherein:
a height of an uppermost surface of the upper conductive line in the second direction is equal to a height of an uppermost surface of the vertical channel portion in the second direction.

9. The semiconductor memory device of claim 1, wherein:
a height of an uppermost surface of the second gate insulating layer in the second direction is greater than a height of an uppermost surface of the vertical channel portion in the second direction.

10. The semiconductor memory device of claim 1, wherein an uppermost surface of the second gate insulating layer in the second direction contacts the conductive contact pattern.

11. A semiconductor memory device comprising:
a substrate;
a conductive line disposed on the substrate;
a horizontal channel portion extending in a first direction on the conductive line and partially covering the conductive line;
a separation insulating layer disposed on the horizontal channel portion;
a gate insulating layer comprising a first portion on the conductive line and a second portion that extends in a second direction that is perpendicular to the substrate;
a vertical channel portion between the gate insulating layer and the separation insulating layer, the vertical channel portion extending in the second direction; and
a spacer on the first portion of the gate insulating layer,
wherein a first material included in the horizontal channel portion is different from a second material included in the vertical channel portion.

12. The semiconductor memory device of claim 11, wherein the first material includes high-mobility IGZO (InGaZnO), ITO (InSnO), IWO (InWO), or n-type polysilicon, or a combination thereof.

13. The semiconductor memory device of claim 11, wherein the second material includes low-mobility IGZO (InGaZnO), ITO (InSnO), IWO (InWO), or polysilicon, or a combination thereof.

14. The semiconductor memory device of claim 11, wherein a thickness of the horizontal channel portion in the second direction is different from a thickness of the vertical channel portion in the first direction.

15. The semiconductor memory device of claim 14, wherein:
the thickness of the horizontal channel portion in the second direction ranges from about 3 nm to about 10 nm, and
the thickness of the vertical channel portion in the first direction ranges from about 3 nm to about 10 nm.

16. The semiconductor memory device of claim 11, wherein:
a height of an uppermost surface of the gate insulating layer in the second direction is greater than a height of an uppermost surface of the vertical channel portion in the second direction.

17. A semiconductor memory device comprising:
a substrate;
a bit line extending in a first direction on the substrate;
a channel structure provided on the bit line;
a gate insulating layer surrounding a sidewall of the channel structure and an upper surface of the bit line;
a spacer disposed on a horizontal portion of the gate insulating layer; and
a word line that contacts an upper surface of the spacer and extends along a sidewall of the gate insulating layer in a second direction that is perpendicular to the substrate;
a landing pad disposed on the channel structure;
a capacitor structure including a lower electrode connected to the landing pad,
wherein the channel structure includes a horizontal channel portion that is parallel to the bit line and a vertical channel portion that protrudes perpendicularly from the upper surface of the bit line, and
a composition of the vertical channel portion is different from a composition of the horizontal channel portion.

18. The semiconductor memory device of claim 17, wherein a material included in the horizontal channel portion has a lower contact resistivity than a material included in the vertical channel portion.

19. The semiconductor memory device of claim 17, wherein a thickness of the horizontal channel portion in the second direction is different from a thickness of the vertical channel portion in the first direction.

20. The semiconductor memory device of claim 17, wherein:
the horizontal channel portion includes high-mobility IGZO (InGaZnO), ITO (InSnO), IWO (InWO), or n-type polysilicon, or a combination thereof,
the vertical channel portion includes low-mobility IGZO (InGaZnO), ITO (InSnO), IWO (InWO), or polysilicon, or a combination thereof.
